(19) United States
(12) Patent Application Publication
(10) Pub. No.: US 2014/0311619 A1
(43) Pub. Date: Oct. 23, 2014

(54) FUEL FILLER GUN WITH ADVERTISEMENT DISPLAY SCREEN AND ENERGY SUPPLY

(71) Applicant: Alvern Media GmbH, Hamburg (DE)

(72) Inventors: Arnold Herp, Moehrendorf (DE); Joerg Peter Strasburger, Hamburg (DE); Sven Wucherpfennig, Hamburg (DE)

(73) Assignee: Alvern Media GmbH, Hamburg (DE)

(21) Appl. No.: 14/363,344

(22) PCT Filed: Dec. 7, 2012
(86) PCT No.: PCT/EP2012/074822

§ 371 Date: Jun. 6, 2014

(30) Foreign Application Priority Data
Dec. 8, 2011 (DE) 10 2011 058173.0

(51) Int. Cl. B67D 7/42; H03K 17/94; B67D 7/04

(52) U.S. Cl. CPC B67D 7/426; B67D 7/04; H03K 17/94
USPC 141/1; 141/94; 307/116

(57) ABSTRACT

The invention relates to a retrofit kit for a filler gun or a filler gun of a fuel pump with an integrated generator for generating electric energy. The retrofit kit or the filler gun contains: a sensor device which is equipped to detect a fueling process of the filler gun; a reproduction device which is equipped to reproduce information; and an electric energy source which supplies the reproduction device with electric energy on the basis of the detection of the fueling process.

Various embodiments relate to devices attachable to a nozzle of a fuel pump, nozzles of a fuel pump, methods for controlling a device attachable to a nozzle of a fuel pump and methods for controlling a nozzle of a fuel pump.

Fuel nozzles of fuel pumps, for example at a fuel station, are often equipped with a static informational display, for example with an advertisement printed on paper.

The advertisement up to now being attached to the fuel nozzle normally is only recognized subconsciously. This disadvantage should be resolved by various embodiments. According to various embodiments the attention can specifically be directed to the advertising surface before and after the refueling process by suitable actors, and associations can be triggered by conditioning.

A problem of the invention is to provide electric energy for dynamically creating an informational display at a fuel nozzle of fuel pumps, for example with the help of lighting, sound output, image output, or video output.

The problem is solved by devices, fuel nozzles, and methods according to the independent claims. Further embodiments arise from the dependent claims.

In one embodiment a device may be provided. The device may be attachable to a fuel nozzle of a fuel pump. The device may include a sensor device configured to recognize a refueling process of the fuel nozzle (in other words: for recognizing that a refueling process starts soon, is already proceeding, or is stopped, for example by recognizing that a motor vehicle has been driven to the fuel pump or that a person is coming closer to the fuel pump or that the fuel nozzle has been taken out of the retainer in the fuel pump). The device may further include an output device configured to output information. The device may further include an electric power supply configured to provide electric energy to the output device based on the recognition of the refueling process.

The electric power supply may be configured for energy harvesting. This implies that the electric power supply converts energy (for example a small amount of energy), which is present in the surroundings of the device, to electric energy.

The electric power supply may include an induction device which may be configured to induce a voltage by a magnet in a turbine within the fuel nozzle, for example by rotating magnets of a turbine in the fuel nozzle driven by fuel. The energy (voltage/current) generated by the rotating magnets in the fuel supply line may be derived wirelessly by coils exterior to the fuel supply line (the principle of an electric generator).

The electric power supply may include a contact configured to receive energy from the interior of the fuel nozzle.

The electric power supply may include or may be a battery.

The electric power supply may include or may be an accumulator.

According to various embodiments the accumulator may be charged in a fuel pump in which the fuel nozzle may be hooked in.

The electric power supply may include or may be a capacitor.

The electric power supply may include or may be a photovoltaic cell.

The electric power supply may include or may be a device for generating energy. The device for generating energy may be configured to generate electric energy from the movement of a user of the fuel nozzle.

The electric power supply may include or may be an automatic clockwork.

The electric power supply may include or may be a piezoelectric element.

The electric power supply may include or may be a thermoelectric element.

The electric power supply may include or may be a fuel cell.

The device may further include an energy storage as explained below in more detail.

The device may further include a controller as explained below in more detail.

The device may further include an interface as described below in more detail.

The device may further include a data memory as explained below in more detail.

The energy storage may be configured to store electric energy.

The energy storage may include a fuel cell, a battery, an accumulator, and/or a capacitor.

The controller may be configured to control the supply of electric energy to the output device based on the recognition of the refueling process.

The controller may be configured to control the supply of electric energy to the output device such that the output device is provided with electric energy before the start of the recognized refueling process.

The controller may be configured to control the supply of electric energy to the output device during the recognized refueling process.

The controller may be configured to control the supply of electric energy to the output device such that the output device is provided with electric energy for a given time period after an end of the recognized refueling process.

The controller may include or may be a programmable logic.

The controller may include or may be a FPGA (Field Programmable Gate Array).

The controller may include or may be a PAL (Programmable Array Logic).

The controller may include or may be a microcontroller.

The interface may be configured to receive data.

The data may include or may be information.

The data may include or may be controlling information for the controller.

The interface may be configured to receive the data by serial transmission.

The interface may be configured to receive the data by wired transmission.

The interface may be configured to receive the data by parallel transmission.

The interface may be configured to receive the data by Ethernet.

The interface may be configured to receive the data by USB (Universal Serial Bus).

The interface may be configured to receive the data by FireWire.

The interface may be configured to receive the data by Thunderbolt, Î2C (I square C), SPI (Serial Peripheral Interface) and/or RS232.

The interface may be configured to receive the data by wireless transmission.

The interface may be configured to receive the data by WLAN (Wireless Local Area Network).

The interface may be configured to receive the data by Bluetooth.

The interface may be configured to receive the data by infrared data transmission.

The interface may be configured to receive the data by mobile communication.

The data memory may be configured for storing data.

The stored data may be received via the interface.

The data may include or may be information.

The data may include or may be controlling information for the controller.

The data memory may include or may be an EPROM (Erasable Programmable Read-Only Memory).

The data memory may include or may be an EEPROM (Electrically Erasable Programmable Read-Only Memory).

The data memory may include or may be a flash memory.

The data memory may be arranged integrated or interchangeable. If it is configured interchangeable, it also serves as an interface for exchanging data.

The device may further include a water protection (not shown) configured to protect the device against water, for example splashing water (for example from cleaning a window of the vehicle) or rainwater.

The device may further include an electric shield or a magnetic shield configured to avoid or reduce electric and/or magnetic interaction towards the exterior of the device.

The sensor device may include or may be a shock sensor.

The sensor device may include or may be an acceleration sensor.

The sensor device may include or may be a light sensor.

The sensor device may include or may be a distance sensor.

The sensor device may include or may be a touch sensible sensor.

The touch sensible sensor may include or may be a capacitive touch sensor.

The touch sensible sensor may include or may be an inductive touch sensor.

The sensor device may include or may be a noise sensor (for example a microphone).

The sensor device may include or may be a motion sensor.

The sensor device may include or may be a temperature sensor.

The sensor device may include or may be a pressure sensor.

The sensor device may include or may be a position sensor.

The sensor device may include or may be a gyroscope.

The output device may include or may be a speaker.

The output device may include or may be a light emitting diode.

The output device may include or may be a plurality of light emitting diodes.

The output device may include or may be a light emitting diode and an optical light guide.

The output device may include or may be a light emitting diode and a plurality of optical light guides.

The output device may include or may be a plurality of light emitting diodes and a plurality of optical light guides.

The output device may include or may be a light emitting foil.

The output device may include or may be a display.

The output device may include or may be a mechanical actuator.

The output device may include or may be a vibration motor.

The output device may include or may be an odor generator.

The information may include or may be sound information.

The sound information may include or may be speech.

The sound information may include or may be music.

The information may include or may be a flash pattern.

The information may include or may be an image.

The information may include or may be a photo.

The information may include or may be a video.

The information may include or may be a mechanical rhythm.

According to an embodiment the fuel nozzle of a fuel pump may be provided. The fuel nozzle may include: a sensor device configured to recognize a refueling process of the fuel nozzle; an output device configured to output information; and an electric power supply configured to supply electric energy to the output device based on the recognition of the refueling process.

The fuel nozzle may further include a turbine having magnets. The electric power supply may include an induction device which may be configured to induce a voltage by the magnet.

According to an embodiment a fuel nozzle of a fuel pump may be provided. The fuel nozzle may include a turbine having a magnet.

According to an embodiment a method for controlling a device attachable to a fuel nozzle of a fuel pump may be provided. The method may include: recognizing a refueling process of the fuel nozzle; outputting information by an output device; and supplying electric energy to the output device based on the recognition of the refueling process.

According to an embodiment a method for controlling a fuel nozzle of a fuel pump may be provided. The method may include: recognizing a refueling process of a fuel nozzle; outputting information by an output device; and supplying electric energy to the output device based on the recognition of the refueling process.

Exemplary embodiments of the invention are shown in the figures and are explained in more detail in the following.

It is shown in

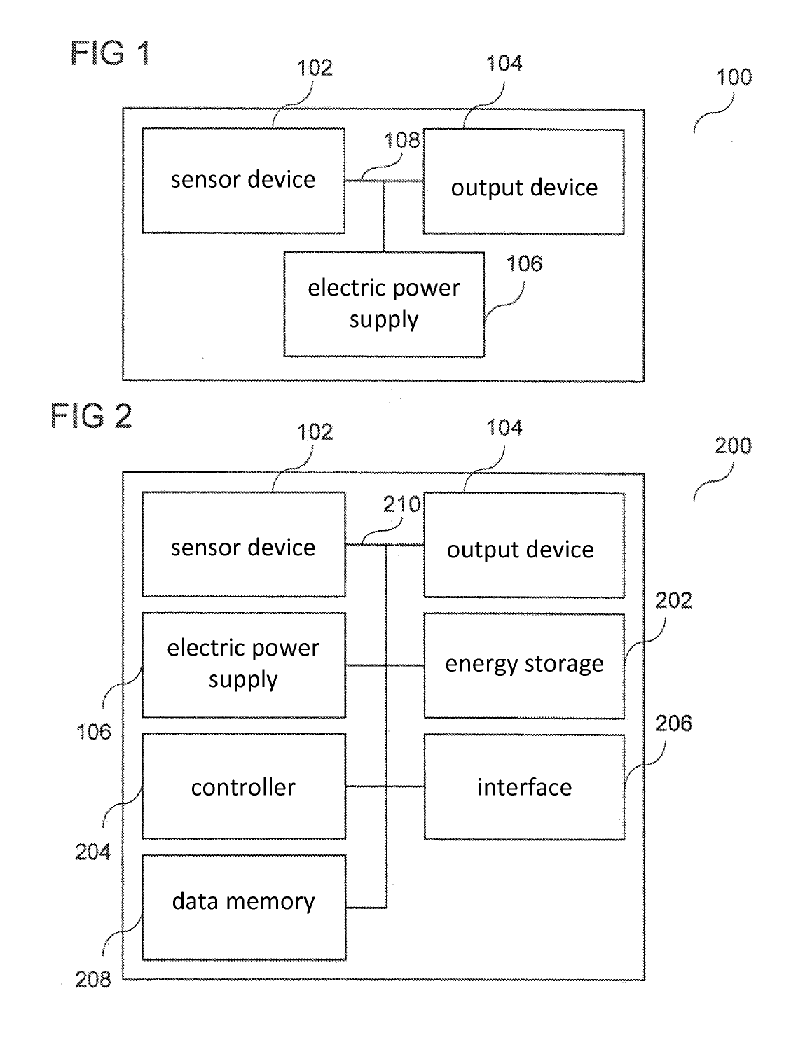

FIG. 1 a device according to an exemplary embodiment;

FIG. 2 a device according to an exemplary embodiment;

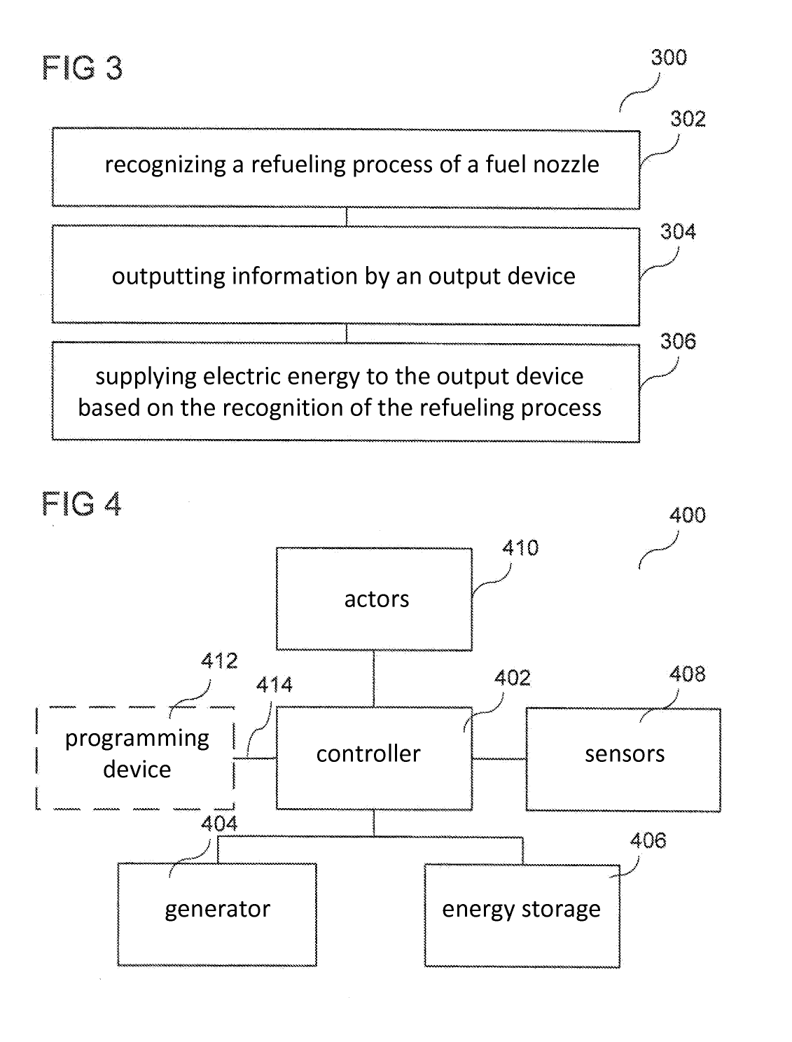

FIG. 3 a flow chart representing a method according to an exemplary embodiment;

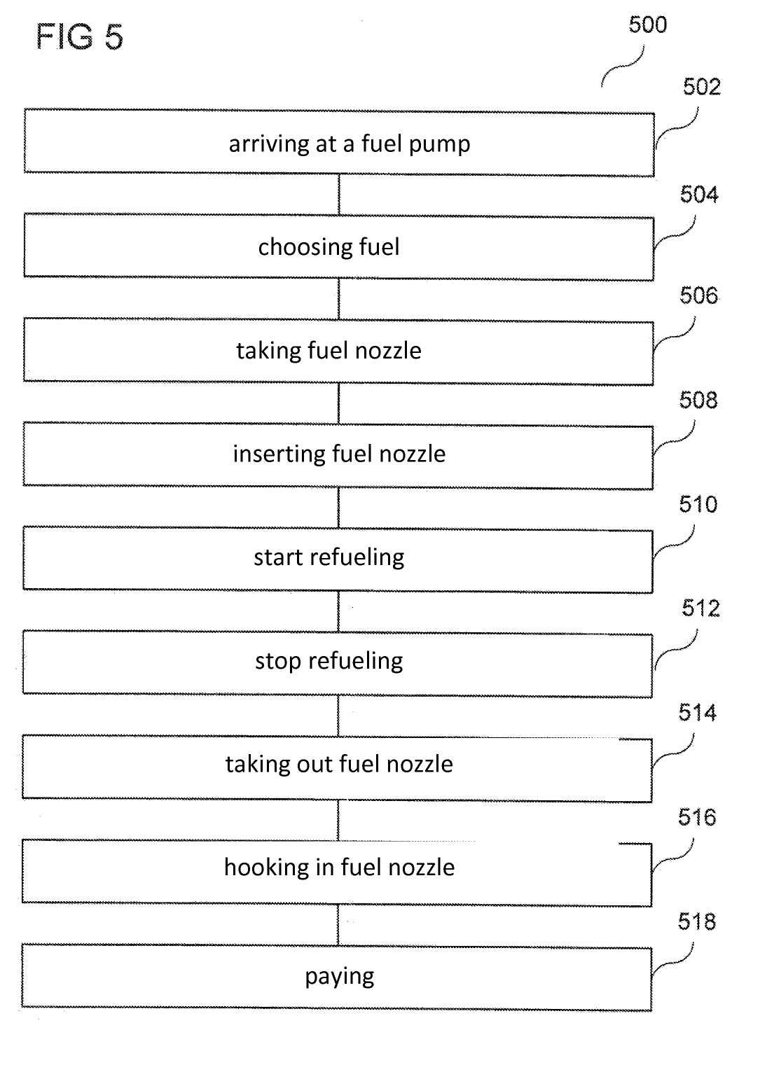

FIG. 4 a device according to an exemplary embodiment;

FIG. 5 a flow chart representing a refueling process according to an exemplary embodiment;

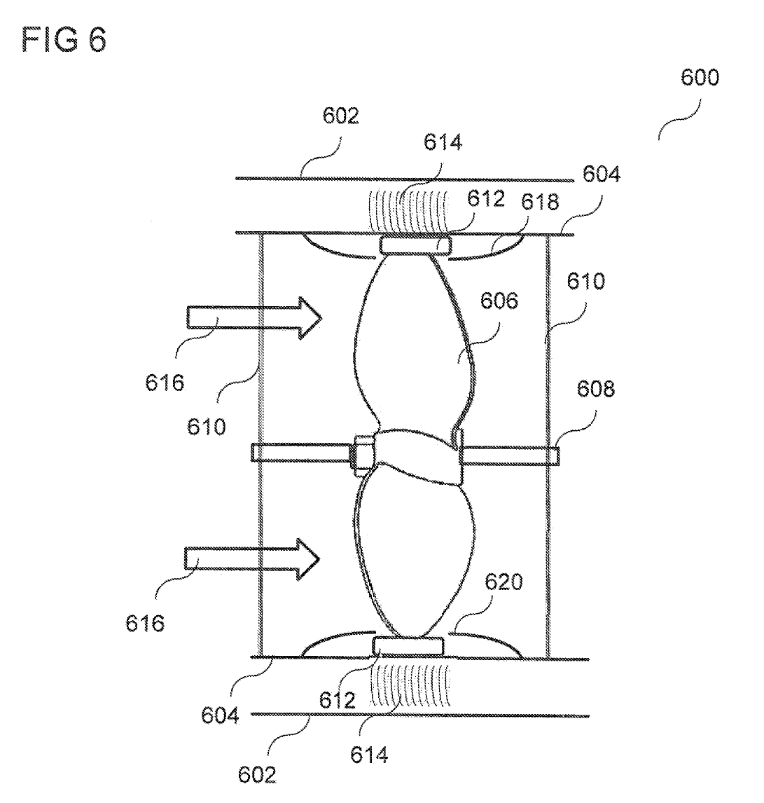

FIG. 6 a turbine according to an exemplary embodiment;

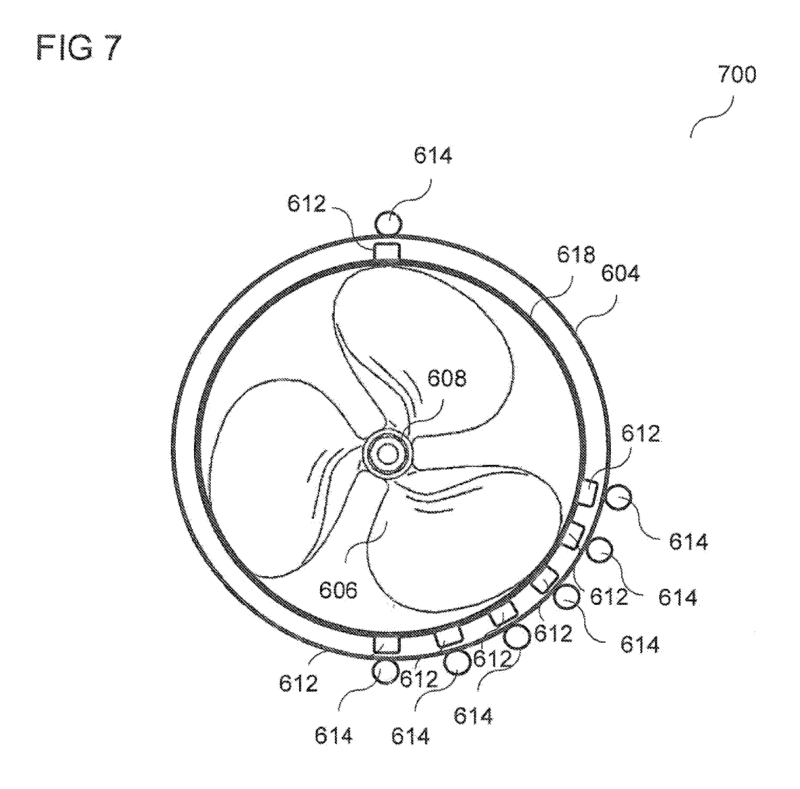

FIG. 7 a turbine according to an exemplary embodiment; and

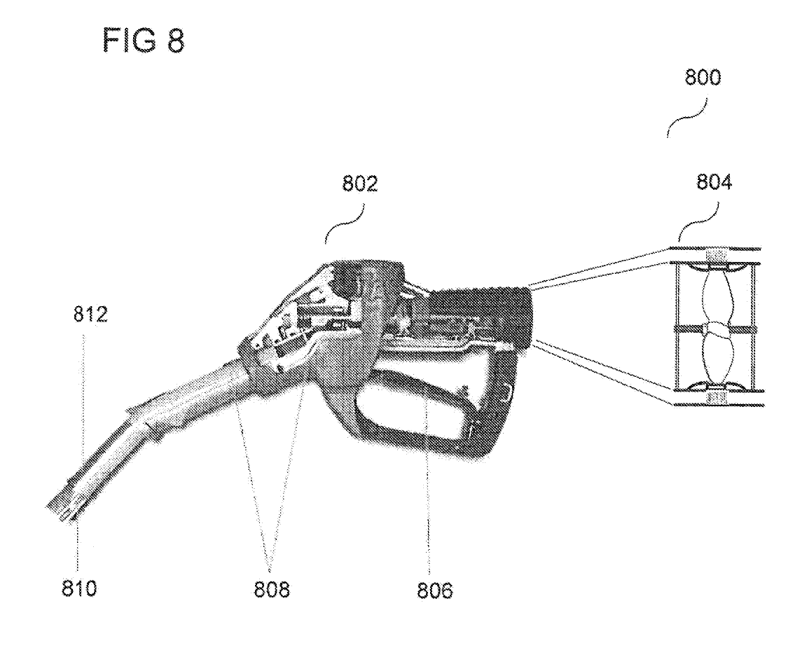

FIG. 8 a fuel nozzle according to an exemplary embodiment.

In context of this description terms like “connected”, “attached” and “coupled” are used for describing a direct and/or an indirect connection, a direct and/or indirect attachment and a direct or indirect coupling. In the figures identical or same elements are characterized by the same reference signs where this is practicable.

Embodiments of a device and embodiments of a fuel nozzle are described. It has to be understood that features of the device may similarly apply to the fuel nozzle and vice versa. It has also to be understood that features which are described in the context of the device or the fuel nozzle may also be applied to a corresponding method and vice versa.

In the following, terms like “fuel nozzle” and “refueling nozzle” are used synonymously.

FIG. 1 shows a device 100 according to an exemplary embodiment. The device 100 may be attachable to a fuel nozzle of a fuel pump (not shown). The device 100 may include a sensor device 102 configured to recognize a refueling process of the fuel nozzle. The device 100 may further include an output device 104 configured to output information. The device 100 may further include an electric power supply 106 configured for supplying electric energy to the output device 104 based on the recognizing of the refueling process. The sensor device 102, the output device 104, and the electric power supply 106 may be coupled by a line, for example a cable, or any other connection 108 which enables the transfer of information and/or electric energy.

A “refueling process” may be understood as a process during which fuel flows through the fuel nozzle.

The device 100 may be provided to direct the attention of a refueling person by optical and/or acoustical stimuli towards a desired area.

The electric power supply 106 may be configured to carry out energy harvesting. This implies that the electric power supply converts energy (for example a small amount of energy) which is present in the surroundings of the device 100 in electric energy.

The electric power supply 106 may include an induction device which may be configured to induce a voltage by a magnet in a turbine of the fuel nozzle.

The electric power supply 106 may comprise coils which may be configured to receive energy from the interior of the fuel nozzle.

The electric power supply 106 may include a contact which may be configured to receive energy from the interior of the fuel nozzle.

The electric power supply 106 may include or may be a battery.

The electric power supply 106 may include or may be an accumulator.

According to various embodiments the accumulator may be charged in a fuel pump in which the fuel nozzle may be hooked in.

The electric power supply 106 may include or may be a capacitor.

The electric power supply 106 may include or may be a photovoltaic cell.

The electric power supply 106 may include or may be a device for generating energy. The device for generating energy may be configured to generate electric energy from a movement of a user of the fuel nozzle.

The electric power supply 106 may include or may be an automatic clockwork.

The electric power supply 106 may include or may be a piezoelectric element.

The electric power supply 106 may include or may be a thermoelectric element.

The electric power supply 106 may include or may be a fuel cell.

FIG. 2 shows a device 200 according to an exemplary embodiment. The device 200 may be attachable to a fuel nozzle of a fuel pump (not shown) similar to the device 100 shown in FIG. 1. The device 200 may include a sensor device 102 configured to recognize a refueling process of the fuel nozzle similar to the device 100 shown in FIG. 1. The device 200 may further include an output device 104 configured to output information similar to the device 100 shown in FIG. 1. The device 200 may further include an electric power supply 106 configured to supply electric energy to the output device 104 based on the recognition of the refueling process, similar to the device 100 of FIG. 1. The device 200 may further include an energy storage 202 as explained below in more detail. The device may further include a controller 204 as explained below in more detail. The device 200 may further include an interface 206 as explained below in more detail. The device 200 may further include a data memory 208 as explained below in more detail. The sensor device 102, the output device 104, the power supply 106, the energy storage 202, the controller 204, the interface 206, and the data memory 208 may be coupled, for example by a wire, for example by a cable, or by any other connection 210 which enables the transfer of information and/or electric energy.

The energy storage 202 may be configured to store electric energy.

The energy storage 202 may include a fuel cell, a battery, an accumulator, and/or a capacitor.

The controller 204 may be configured to control the supply of electric energy to the output device 104 based on the recognition of the refueling process.

The controller 204 may be configured to control the supply of electric energy to the output device 104 such that the output device 104 is supplied with electric energy before the start of the recognized refueling process.

The controller 204 may be configured to control the supply of electric energy to the output device 104 during the recognized refueling process.

The controller 204 may be configured to control the supply of electric energy to the output device 104 such that the output device 104 is supplied with electric energy for a given time interval after the end of the recognized refueling process.

The controller 204 may include or may be a programmable logic.

The controller 204 may include or may be a FPGA (Field Programmable Gate Array).

The controller 204 may include or may be a PAL (Programmable Array Logic).

The controller 204 may include or may be a microcontroller.

The interface 206 may be configured to receive data.

The data may include or may be information.

The data may include or may be controlling information for the controller 204.

The interface 206 may be a wired interface, for example a serial interface or a parallel interface, a wireless interface or a mechanical interface (for example by exchanging a storage medium).

The interface 206 may be configured to receive the data by serial transmission.

The interface 206 may be configured to receive the data by parallel transmission.

The interface 206 may be configured to receive the data by wired transmission.

The interface 206 may be configured to receive the data by Ethernet.

The interface 206 may be configured to receive the data by USB (Universal Serial Bus).

The interface 206 may be configured to receive the data by FireWire.

The interface 206 may be configured to receive the data by Thunderbolt.

The interface 206 may be configured to receive the data by a wireless transmission.

The interface 206 may be configured to receive the data by WLAN (Wireless Local Area Network).

The interface 206 may be configured to receive the data by Bluetooth.

The interface 206 may be configured to receive the data by infrared data transmission.

The interface 206 may be configured to receive the data by mobile communication.

The data memory 208 may be configured for storing data.

The data memory 208 may also be configured for exchanging data.

The data may include or may be information.

The data may include or may be controlling information for the controller 204.

The data memory 208 may include or may be an EPROM (Erasable Programmable Read-Only Memory).

The data memory 208 may include or may be an EEPROM (Electrically Erasable Programmable Read-Only Memory).

The data memory 208 may include or may be a flash memory.

The device 200 may further include a water protection (not shown), configured to protect the device against water, for example splashing water (for example from cleaning a window of the vehicle) or against rainwater.

The device 200 may further include an electric shield configured to avoid or reduce electric and/or magnetic interaction towards the exterior of the device 200.

The sensor device 102 may include or may be a shock sensor.

The sensor device 102 may include or may be an acceleration sensor.

The sensor device 102 may include or may be a light sensor.

The sensor device 102 may include or may be a distance sensor.

The sensor device 102 may include or may be a touch sensible sensor.

The touch sensible sensor may include or may be a capacitive touch sensor.

The touch sensible sensor may include or may be an inductive touch sensor.

The sensor device 102 may include or may be a noise sensor (for example a microphone).

The sensor device 102 may include or may be a motion sensor.

The sensor device 102 may include or may be a temperature sensor.

The sensor device 102 may include or may be a pressure sensor.

The sensor device 102 may include or may be a position sensor.

The sensor device 102 may include or may be a gyroscope.

The output device 104 may include or may be a speaker.

The output device 104 may include or may be a light emitting diode.

The output device 104 may include or may be a plurality of light emitting diodes.

The output device 104 may include or may be a light emitting diode and an optical light guide.

The output device 104 may include or may be a light emitting diode and a plurality of optical light guides.

The output device 104 may include or may be a plurality of light emitting diodes and a plurality of optical light guides.

The output device 104 may include or may be a light emitting foil.

The output device 104 may include or may be a display.

The output device 104 may include or may be a mechanical actuator.

The output device 104 may include or may be a vibration motor.

The output device 104 may include or may be an odor generator.

The information may include or may be sound information.

The sound information may include or may be speech.

The sound information may include or may be music.

The information may include or may be a flash pattern.

The information may include or may be an image.

The information may include or may be a photo.

The information may include or may be a video.

The information may include or may be a mechanical rhythm.

According to an embodiment the fuel nozzle of a fuel pump may be provided. The fuel nozzle may include: a sensor device configured to recognize a refueling process of the fuel nozzle; an output device configured to output information; and an electric power supply configured to supply electric energy to the output device based on the recognition of the refueling process.

The fuel nozzle may further include a turbine having magnets. The electric power supply may include an induction device which may be configured to induce a voltage through the magnet.

According to an embodiment a fuel nozzle of a fuel pump may be provided. The fuel nozzle may include a turbine having a magnet.

FIG. 3 shows a flow chart 300 representing a method according to an exemplary embodiment. The method may be a method for controlling a device attachable to a fuel nozzle of a fuel pump. In 302 a refueling process of the fuel nozzle may be recognized. In 304 information may be outputted by the output device. In 306 the output device may be provided with electric energy based on the recognition of the refueling process.

The method is configured to direct the attention of a refueling person to a desired area by optical and/or acoustical stimuli.

According to an embodiment a method for controlling a fuel nozzle of a fuel pump may be provided. The method may include: recognizing a refueling process of a fuel nozzle; outputting information via an output device; and supplying electric energy to the output device based on the recognition of the refueling process.

FIG. 4 shows a device 400 according to an exemplary embodiment. The device 400 may be a device for targeted control of the attention during the refueling. The device 400 may be based on a programmable controller 402 with a memory and connected sensors 408 and actors 410 wherein the electric energy needed to drive these elements is generated by energy harvesting (for example, by a generator 404) and is temporarily stored in an energy storage 406. Via an interface 414 the functionality of the method may be changed if necessary and may be adapted, for example by a programming device 412.

FIG. 5 shows a flow diagram 500 representing a refueling process according to an exemplary embodiment. The refueling process may include in 502 the arrival at a fuel pump. In 504 fuel may be chosen. In 506 the fuel nozzle may be taken from e.g. a fuel pump. In 508 the fuel nozzle may be inserted into a fuel opening of a vehicle or a canister. In 510 the refueling may be started. In 512 the refueling may be stopped. In 514 the fuel nozzle may be taken out. In 516 the fuel nozzle may be hooked into the fuel pump. In 518 payment may occur.

For example in step 502 the attention may be directed to a sort of fuel for example by cyclical blinking of the output device for example an LED. In 506 the device may be “woken up” (this means for example the transition from a stand-by mode to normal operation) for example by supplying the output device with electric energy from the energy source and the refueling process may begin. In 510 the attention of the user may be optically directed to the advertising surface for example by illuminating the advertising medium of the output device. In 516 one may be thanked with an acoustical signal (for example in form of a jingle) by the output device and the output device may for example be transferred into the stand-by (in other words an energy saving mode), for example by not supplying electric energy of the energy source to the output device. In 510 and 512 energy harvesting may be carried out while the fuel flows.

FIG. 6 shows a cutaway view 600 of a turbine according to an exemplary embodiment. The turbine 600 may be a part of a generator which generates electric energy from the kinetic energy of the fuel flowing through the fuel nozzle. An exterior wall 602 of a device attachable to the fuel nozzle (or the fuel supply line) protects a coil 614 or several coils 614. The fuel nozzle, from which one segment 604 (for example a piece of pipe of the fuel nozzle) is shown, may include a propeller 606 seated on a (rotation) shaft 608. The shaft 608 may be attached to the fuel nozzle via fixing means 610. A magnet 612 or several magnets 612 (for example permanent magnets) may be attached to the propeller 606, for example by fixing means 618. The propeller 606 may be driven by a fuel flow in a direction of the arrows 616 and a voltage is induced in a coil 614 (or the coils 614) by the magnet 612 (or the magnets 612).

FIG. 7 shows a view 700 in flow direction of the turbine showed in FIG. 6. In one embodiment a propeller may be provided which rotates vertically (or horizontally). For this reason the pipe may be flattened at opposing areas in order to take in the propeller. The coils may be arranged outside.

A diameter d of a pipe of the fuel nozzle may be 3 cm. The flow F through the pipe may be 300 to 500 cm³/s. A slip of the propeller may be 30%. From these parameters a flow speed vK of the fuel may be calculated from which with the slip the revolution speed of the generator may be estimated (in rounds per second (RPS)).

The area corresponding to the diameter d of the inside of the pipe of a fuel nozzle may be 9 cm². Having a flow F of 500 cm³/s the length of the fuel amount in the pipe may be 55 cm (or 33 cm at 300 cm³/s flow). The flow speed vK 500 may also theoretically be 55 cm/s. Having slip of S (for example 30%) the rotation speed D of the generator would be vK×(100−S)/100 (i.e. 38,5 rotations per second). This may be taken into account by the configuration of the generator as a slow speed generator.

FIG. 8 shows a fuel nozzle 800 according to an exemplary embodiment. The fuel nozzle 800 may have a main body 802 of the fuel nozzle 800 and a generator 804, a trigger arm 806, a fuel recovery system 808, a sensor line 810 and an exit pipe 812.

In one embodiment a device may be provided as a programmable system including the components energy harvesting, energy storage, controller with data memory and interfaces, sensors and actors attached to or integrated in a fuel nozzle for fuels. The device may be adaptable with respect to its functionality with the help of an external programming device via an interface to the controller.

In one embodiment energy harvesting may be carried out by a photovoltaic cell, a peltier element, or a piezo element, for example configured as peltier element, for example configured as generator, which may be driven by the flow of fuel and which may convert flow energy in electric energy.

In one embodiment an energy storage may be provided. Either integrated or interchangeable, for example including a fuel cell, a battery, an accumulator, or a capacitor for example configured as rechargeable accumulator.

In one embodiment sensors may be provided for recognizing light, movement, position angles, vibration and/or pressure.

In one embodiment actors may be provided for provoking attention, for example via vibration motors, speakers, lightning means (for example LEDs or illumination foil), or odor generators.

In one embodiment a controller data memory and interfaces may be provided including at least a programmable logic element (PAL, FPGA) or a microcontroller.

In an embodiment a programming device may be provided for modifying the functionality of the device for example the temporal sequence or duration of e.g., the illumination or the sounds. The programming device may transmit the data via a radio interface or a wired interface at the device.

Although the invention is shown and explained with reference to specific embodiments, it should be understood by persons skilled in the art that numerous amendments of the embodiments in details thereof may be carried out without departing from the spirit and the scope of the invention as it is defined by the following claims. The scope of the invention may therefore be defined by the attached claims and it is intended that all changes which may fall under the literal sense or the equivalent scope of the claims may be included.

1. A device attachable to a fuel nozzle of a fuel pump, the device comprising:
a sensor device configured to recognize a refueling process of the fuel nozzle;
an output device configured to output information; and
an electric energy source configured to supply electric energy to the output device based on the recognition of the refueling process,
wherein the electric energy source comprises an induction device configured to induce a voltage by a magnet in a turbine of the fuel nozzle.

2. (canceled)

3. Device according to claim 1 further comprising:
an energy storage configured to store electric energy.

4. Device according to claim 1 further comprising:
a controller configured to control the supply of electric energy to the output device based on the recognition of the refueling process.

5. Device according to claim 4,
wherein the controller is configured to control the supply of electric energy to the output device such that the output device may be supplied with electric energy before the start of the recognized refueling process.

6. Device according to claim 4,
wherein the controller is configured to control a supply of electric energy to the output device such that the output device may be supplied with electric energy over a given duration after the end of the recognized refueling process.

7. Device according to claim 4,
wherein the controller comprises a programmable logic.

8. Device according to claim 1 further comprising:
an interface, configured to receive data.

9. Device according to claim 8, wherein the data comprise information.

10. Device according to claim 8, further comprising:
a controller configured to control the supply of electric energy to the output device based on the recognition of the refueling process;
wherein the data comprise control information for the controller.

11. A fuel nozzle for a fuel pump, the fuel nozzle comprising:
a sensor device configured to recognize a refueling process of the fuel nozzle;
an output device configured to output information;
an electric energy source configured to supply electric energy to the output device based on the recognition of the refueling process; and
a turbine with a magnet;
wherein the electric energy source comprises an induction device configured to induce a voltage by the magnet.

12. (canceled)

13. Fuel nozzle of a fuel pump, the fuel nozzle comprising a turbine with a magnet.

14. Method for controlling a device attachable to a fuel nozzle of a fuel pump, the method comprising:
recognizing a refueling process of a fuel nozzle;
outputting information with an output device; and
supplying electric energy to the output device based on the recognition of the refueling process by an induction device configured to induce a voltage by a magnet in a turbine of the fuel nozzle.

15. Method for controlling a fuel nozzle of a fuel pump, the method comprising:
recognizing a refueling process of the fuel nozzle;
outputting information with an output device; and
supplying electric energy to the output device based on the recognition of refueling process by an induction device configured to induce a voltage by a magnet in a turbine of the fuel nozzle.
